(19) United States
(12) Patent Application Publication
(10) Pub. No.: US 2020/0243697 A1
(43) Pub. Date: Jul. 30, 2020

(54) SOLAR CELL

(71) Applicant: DUPONT ELECTRONICS, INC., Wilmington, DE (US)

(72) Inventors: WEI HSUAN CHANG, Taoyuan City (TW); YUMI MATSUURA, KANAGAWA (JP); QIJIE GUO, HAINESPORT, NJ (US)

(21) Appl. No.: 16/751,996

(22) Filed: Jan. 24, 2020

Related U.S. Application Data
(60) Provisional application No. 62/797,611, filed on Jan. 28, 2019.
(60) Provisional application No. 62/797,636, filed on Jan. 28, 2019.

(51) Int. Cl. H01L 31/0224; H01L 31/0216; H01L 31/0236; H01L 31/18

(52) U.S. Cl. CPC H01L 31/022475; H01L 31/022483; H01L 31/1884; H01L 31/02167; H01L 31/02366; H01L 31/022425

(57) ABSTRACT

The invention relates to a passivated contact type solar cell and a method for its manufacture. The method comprises the steps of: (i) preparing a substrate comprising: a first semiconductor layer, a tunnel oxide layer on the first semiconductor layer, a second semiconductor layer on the tunnel oxide layer, a first insulating layer on the second semiconductor layer, and a third semiconductor layer on the first semiconductor layer at the other side of the tunnel oxide layer, wherein the second semiconductor layer is 0.2 to 400 nm thick, wherein the first insulating layer comprises one or more openings; (ii) applying a conductive paste in the openings of the first insulating layer, the conductive paste comprising, (a) a conductive powder comprising silver (Ag) and palladium (Pd), (b) a glass frit, and (c) an organic vehicle; and (iii) firing the applied conductive paste to form an electrode. The glass frit may comprise 30 to 90 wt. % of at least one of PbO or Bi₂O₃, 1 to 50 wt. % of B₂O₃, 0.1 to 30 wt. % of SiO₂, and 0.1 to 20 wt. % of Al₂O₃.

### CROSS-REFERENCE TO RELATED APPLICATIONS

This application claims benefit under 35 USC 119(e) of U.S. Provisional Application Ser. No. 62/797,611, and U.S. Provisional Application Ser. No. 62/797,636, both filed Jan. 28, 2019, which applications are incorporated herein for all purposes by reference thereto.

### FIELD OF THE INVENTION

The present invention relates to a passivated contact type solar cell, and more particularly to an electrode thereof and a method for its manufacture.

### TECHNICAL BACKGROUND OF THE INVENTION

A passivated contact type solar cell is required to have sufficient efficiency. Examples of the passivated contact type solar cell are a tunnel oxide passivated contact (TOPcon) type solar cell and a Poly-Si-on-Oxide (POLO) type solar cell.

WO2017163498 discloses a TOPcon type solar cell. The solar cell comprises a tunnel oxide layer formed on a semiconductor substrate; a first conductivity-type semiconductor layer formed on the tunnel oxide layer; a protection film formed on the semiconductor layer; and an electrode. The electrode is formed by screen printing a conductive paste followed by firing it, such that the conductive paste etches the protection film during the firing and electrically contacts with the semiconductor layer.

### SUMMARY OF THE INVENTION

An objective is to provide a passivated contact type solar cell having a sufficient electrical property.

An aspect relates to a method for manufacturing a passivated contact type solar cell, comprising the steps of: (i) preparing a substrate comprising: a first semiconductor layer, a tunnel oxide layer on the first semiconductor layer, a second semiconductor layer on the tunnel oxide layer, a first insulating layer on the second semiconductor layer, and a third semiconductor layer on the first semiconductor layer at the other side of the tunnel oxide layer, wherein the second semiconductor layer is 0.2 to 400 nm thick, wherein the first insulating layer comprises one or more openings; (ii) applying a conductive paste in the openings of the first insulating layer, the conductive paste comprising: (a) a conductive powder comprising silver (Ag) and palladium (Pd), (b) a glass frit, and (c) an organic vehicle; and (iii) firing the applied conductive paste to form an electrode. The conductive powder may comprise a powder of silver (Ag), palladium (Pd), an alloy comprising Ag and Pd, or a mixture thereof. The glass frit may comprise 30 to 90 wt. % of at least one of PbO or Bi₂O₃, 1 to 50 wt. % of B₂O₃, 0.1 to 30 wt. % of SiO₂, and 0.1 to 20 wt. % of Al₂O₃.

Another aspect relates to a conductive paste for a passivated contact type solar cell, the conductive paste comprising: (a) a conductive powder comprising silver (Ag) and palladium (Pd), (b) a glass frit, and (c) an organic vehicle.

Still another aspect relates to a passivated contact type solar cell comprising: (i) a substrate comprising a first semiconductor layer, a tunnel oxide layer on the first semiconductor layer, a second semiconductor layer on the tunnel oxide layer, a first insulating layer on the second semiconductor layer, a third semiconductor layer on the first semiconductor layer at the other side of the tunnel oxide layer, wherein the first insulating layer comprises one or more openings; and (ii) an electrode on the substrate wherein the electrode fills the openings in the first insulating layer and contacts the second semiconductor layer, the electrode comprising: (a) a metal and (b) a glass. In an embodiment, the metal comprises silver (Ag) and palladium (Pd). In an embodiment, the second semiconductor layer is less than 20 nm thick.

A passivated contact type solar cell with a sufficient electrical property can be provided by the present invention.

### BRIEF DESCRIPTION OF THE DRAWINGS

The invention will be more fully understood and further advantages will become apparent when reference is made to the following detailed description of the preferred embodiments of the invention and the accompanying drawings, wherein like reference numerals denote similar elements throughout the several views and in which:

FIGS. 1A through 1C are drawings for explaining a manufacturing process of a passivated contact type solar cell; and

FIGS. 2A through 2C illustrate different possible forms of the pattern of the openings in the first insulating layer of the solar cell.

### DETAILED DESCRIPTION OF THE INVENTION

The method of manufacturing the passivated contact type solar cell comprises the steps of: (i) preparing a substrate, (ii) applying a conductive paste on the substrate, and (iii) firing the applied conductive paste.

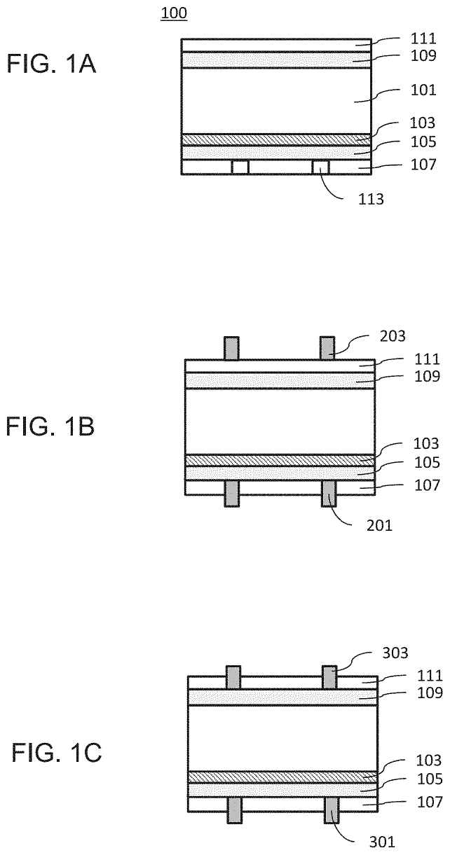

A TOPCon type solar cell as an example of the passivated contact type solar cell is explained hereafter. A TOPCon type solar cell is also called a Poly-Si-on-Oxide (POLO) cell. The passivated contact type solar cell is a TOPCon type solar cell or a POLO type solar cell in an embodiment. A substrate 100 comprising a first semiconductor layer 101, a tunnel oxide layer 103, a second semiconductor layer 105, a first insulating layer 107 and a third semiconductor layer 109 is prepared (FIG. 1A). The first semiconductor layer 101 is a silicon layer in an embodiment. The first semiconductor layer 101 is an n-type silicon layer or a p-type silicon layer in an embodiment. The first semiconductor layer 101 is an n-type silicon layer in another embodiment. The first semiconductor layer 101 is a p-type silicon layer in another embodiment. The tunnel oxide layer 103 is a silicon oxide layer in an embodiment. The tunnel oxide layer 103 is 0.15 to 500 nm thick in an embodiment, 0.2 to 250 nm in another embodiment, 0.25 to 180 nm in another embodiment, 0.3 to 100 nm in another embodiment, 0.4 to 60 nm in another embodiment, 0.5 to 30 nm in another embodiment, 0.6 to 10 nm in another embodiment.

The second semiconductor layer 105 is a silicon layer in an embodiment. The second semiconductor layer 105 is a poly silicon layer in another embodiment. The second semiconductor layer 105 is a n-type silicon layer or a p-type silicon layer in another embodiment. The second semiconductor layer 105 is a n-type silicon layer in another embodiment. The second semiconductor layer 105 is a p-type silicon layer in another embodiment. The second semiconductor layer 105 is 0.2 nm thick or more in an embodiment, 0.25 nm thick or more in another embodiment, 0.5 nm thick or more in another embodiment, 1 nm thick or more in another embodiment, 3 nm thick or more in another embodiment, 5 nm thick or more in another embodiment. The second semiconductor layer 105 is 400 nm thick or less, 300 nm thick or less in another embodiment, 200 nm thick or less in another embodiment, 100 nm thick or less in another embodiment, 50 nm thick or less in another embodiment.

The third semiconductor layer 109 is a silicon layer in an embodiment. The third semiconductor layer 109 is a n-type silicon layer or a p-type silicon layer in another embodiment. The third semiconductor layer 109 is a n-type silicon layer in another embodiment. The third semiconductor layer 109 is a p-type silicon layer in another embodiment. The third semiconductor layer 109 is 0.2 to 50 nm thick, 0.25 to 40 nm in another embodiment, 0.3 to 30 nm in another embodiment, 0.35 to 20 nm in another embodiment, 0.4 to 10 nm in another embodiment.

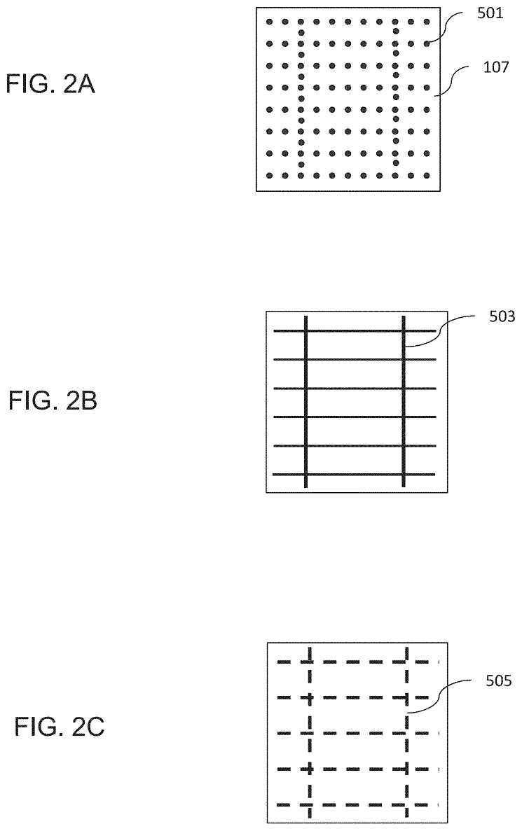

The first insulating layer 107 comprises one or more openings 113. The first insulating layer 107 can be formed, for example, by thermal oxidation. In an embodiment, the first insulating layer 107 is selected from the group consisting of Si₃N₄, TiO₂, and a combination thereof. The openings 113 are formed by partially removing the first insulating layer 107 by way of laser ablation. The pattern of the openings 113 is not limited. For example, the first insulating layer 107 comprises one or more openings with pattern of dots 501 as illustrated in FIG. 2A in an embodiment, lines 503 in another embodiment as illustrated in FIG. 2B, or dashed lines 505 in another embodiment as illustrated in FIG. 2C. The diameter of the dots 501 is 1 to 400 μm in an embodiment. The lines 503 or dashed lines 505 are 1 to 2000 μm wide respectively in an embodiment. The diameter of the dots 501, the width of the lines 503 and dashed lines 505 can be measured by scanning electron microscopy (SEM).

The substrate 100 optionally further comprises a second insulating layer 111 in an embodiment as shown in FIG. 1A. There is no limitation whether the second insulating layer 111 comprises the openings or not. The second insulating layer 111 comprises no openings in an embodiment. The second insulating layer 111 comprises openings in another embodiment.

A conductive paste 201 is applied in the openings 113 of the first insulating layer 107 (FIG. 1B). The conductive paste 201 is applied over the openings 113 where the conductive paste 201 fills the openings 113. Another conductive paste 203 is applied on the second insulating layer 111 in another embodiment. The conductive paste 203 applied on the applied on the second insulating layer 111 is a fire-through type when the second insulating layer 111 does not comprise the openings. A fire-through type conductive paste is a paste capable of etching the insulating layer 111 during firing. The same conductive paste is applied on the second insulating layer 111 in another embodiment. The same conductive paste is available on the second insulating layer 111 when the second insulating layer 111 comprise the openings as well as the first insulating layer 107. The conductive paste 203 is applied in the openings of the second insulating layer 111 in another embodiment. The conductive paste 203 is applied over the openings where the conductive paste 203 fills the openings in another embodiment.

A conductive paste 203 is applied on the third semiconductor layer when the substrate does not comprise the second insulating layer 111 in another embodiment.

The conductive pastes 201, 203 are applied by screen printing, stencil printing or dispensing in an embodiment. The pastes have the same composition in some embodiments and different compositions in others.

The applied conductive pastes 201, 203 are then dried for 1 to 30 minutes at a temperature of about 80 to 200° C. in an embodiment.

The conductive pastes 201, 203 are fired to form the electrodes 301, 303 in an embodiment (FIG. 1C). In an embodiment, the firing is conveniently accomplished using a multi-zone belt furnace in which the set point in the hottest zone (which is often termed a “peak set point temperature”) is about 400 to 950° C. It has been found that under such a heat treatment, the semiconductor may experience an actual peak temperature in the range of about 350 to 900° C. The electrodes 301, 303 contact the second semiconductor layer 105 and the third semiconductor layer 109 after firing.

The first semiconductor layer 101 is a n-type layer, the second semiconductor layer 105 is a n-type layer and the third semiconductor layer 109 is a p-type layer in another embodiment. The first semiconductor layer 101 is a p-type layer, the second semiconductor layer 105 is a p-type layer and the third semiconductor layer 109 is a n-type layer in another embodiment.

The substrate 100 comprises the tunnel oxide layers 103 on both sides of the first semiconductor layer 101 in another embodiment. The substrate 100 comprising the tunnel oxide layers 103 on both sides of the first semiconductor layer 101 comprises the second semiconductor layer 105 on the tunnel oxide layer 103 and the third semiconductor layer 109 on the tunnel oxide layer in another embodiment. The substrate 100 further comprises another tunnel oxide layer between the first semiconductor layer and the third semiconductor layer in an embodiment. The third semiconductor layer 109 is 0.2 to 50 nm thick, 0.25 to 40 nm in another embodiment, 0.3 to 30 nm in another embodiment, 0.35 to 20 nm in another embodiment, 0.4 to 10 nm in another embodiment. The second insulating layer 111 comprises one or more of openings in another embodiment.

The conductive paste 201 comprises (a) a conductive powder comprising silver (Ag) and palladium (Pd), (b) a glass frit, and (c) an organic vehicle.

### Conductive Powder

The conductive powder comprises at least one of silver (Ag) or palladium (Pd). The conductive powder comprises silver (Ag) in an embodiment. The conductive powder comprises silver (Ag) and palladium (Pd) in another embodiment. The conductive powder comprises silver (Ag) powder in another embodiment. The conductive powder is a metal powder selected from the group consisting of a Ag powder, a Pd powder, an alloy powder of Ag and Pd, and a mixture thereof in an embodiment. Ag is 60 to 99.9 wt. % in an embodiment, 65 to 99 wt. % in another embodiment, 75 to 98 wt. % in another embodiment, and 82 to 95 wt. % in another embodiment based on the weight of the conductive powder. Pd is 0.1 to 30 wt. % in an embodiment, 1 to 25 wt. % in another embodiment, 2 to 18 wt. % in another embodiment, 3 to 10 wt. % in another embodiment based on the weight of the conductive powder.

The conductive powder is flaky, spherical, undefined, or a mixture thereof in an embodiment. The particle diameter (D50) of the conductive powder is 0.1 to 10 μm in an embodiment, 0.3 to 6 μm in another embodiment, 0.5 to 4 μm in another embodiment, 0.8 to 3.5 μm in another embodiment, and 1 to 2.5 μm in another embodiment. The particle diameter (D50) is measured with a laser diffraction scattering method, e.g. using a Microtrac model X-100 particle size analyzer (available commercially from Microtrac, Inc., Montgomeryville, Pa.).

The conductive powder is a mixture of a Ag powder and a Pd powder in an embodiment. Purity of the Ag powder can be 80% or higher in an embodiment, 90% or higher in another embodiment, 97% or higher in another embodiment. Purity of the Pd powder can be 80% or higher in an embodiment, 90% or higher in another embodiment, 97% or higher in another embodiment.

The conductive powder can further comprise an additional metal in an embodiment. The additional metal is selected from the group consisting of molybdenum (Mo), boron (B), titanium (Ti), copper (Cu), and a mixture thereof.

### Glass Frit

The glass frit melts during firing to adhere to the substrate. Particle diameter of the glass frit can be 0.05 to 5 μm in an embodiment, 0.1 to 3.5 μm in another embodiment, 0.5 to 1.5 μm in another embodiment. Softening point of the glass frit can be 330 to 600° C. in an embodiment, 370 to 600° C. in another embodiment, 400 to 550° C. in another embodiment, 410 to 460° C. in another embodiment. When the softening point is in the range, glass frit can melt properly to obtain the effects mentioned above. Methods known in the art for measuring the softening point of a glass frit include DTA-based methods and the fiber elongation method of ASTM Standard C338-57, which is promulgated by ASTM International, West Conshohocken, Pa., and incorporated herein by reference.

Any glass frit providing the required chemical, mechanical, and electrical properties can be used in formulating the present paste. For example, the glass frit can comprise a lead silicate (Pb—Si) glass, a lead boron silicate (Pb—B—Si) glass, a lead tellurium (Pb—Te) glass, a lead-free bismuth (Bi) glass, a lead-free zinc borosilicate (Zn—B—Si) glass or a mixture thereof in various embodiments. A lead containing glass frit could be excellent from a viewpoint of both softening point and glass fusion characteristics in an embodiment. A lead-free glass frit could be excellent from a viewpoint of environmental-friendly in an embodiment. In various embodiments, the glass frit comprises Pb—B—Si glass, Pb—Si—Al glass, Pb—Te—B glass, Pb—Te—Li glass, Pb—V glass, Bi—Si—B glass, Bi—Te glass, or a mixture thereof.

In some embodiments, the glass frit comprises 30 to 90 wt. % of PbO or Bi₂O₃, 1 to 50 wt. % of B₂O₃, 0.1 to 30 wt. % of SiO₂, 0.1 to 20 wt. % of Al₂O₃.

PbO is 0 to 90 wt. % in an embodiment, 10 to 85 wt. % in another embodiment, 30 to 81 wt. % in another embodiment, 57 to 10 wt. % in another embodiment, based on the weight of the glass frit.

Bi₂O₃ is 0 to 90 wt. % in an embodiment, 10 to 85 wt. % in another embodiment, 30 to 81 wt. % in another embodiment, 57 to 10 wt. % in another embodiment, based on the weight of the glass frit.

B₂O₃ is 3 to 40 wt. % in an embodiment, 5 to 30 wt. % in another embodiment, 6 to 22 wt. % in another embodiment, 8 to 18 wt. % in another embodiment, based on the weight of the glass frit.

SiO₂ is 0.3 to 22 wt. % in an embodiment, 0.5 to 18 wt. % in another embodiment, 0.9 to 15 wt. % in another embodiment, 1 to 10 wt. % in another embodiment, based on the weight of the glass frit.

Al₂O₃ is 0.2 to 16 wt. % in an embodiment, 0.3 to 10 wt. % in another embodiment, 0.4 to 6 wt. % in another embodiment, 0.5 to 3 wt. % in another embodiment, based on the weight of the glass frit.

The glass frit further comprises metal oxides selected from the group consisting of ZnO, BaO, or a combination thereof in another embodiment. The glass frit further comprises ZnO and BaO in another embodiment.

ZnO is 0 to 30 wt. % in an embodiment, 1 to 25 wt. % in another embodiment, 5 to 20 wt. % in another embodiment, 8 to 18 wt. % in another embodiment, based on the weight of the glass frit.

BaO is 0 to 10 wt. % in an embodiment, 0.1 to 8 wt. % in another embodiment, 0.5 to 6 wt. % in another embodiment, 1 to 5 wt. % in another embodiment, based on the weight of the glass frit.

Some examples of glass frits that can be used in the present conductive paste are listed in Table 1 below, showing the oxide content of each example (weight %) and the softening point of the glass measured using a DTA:

TABLE 1

| | | | | | | | | Softening |
|---|---|---|---|---|---|---|---|---|
| Glass # | PbO | Bi₂O₃ | B₂O₃ | SiO₂ | Al₂O₃ | ZnO | BaO | Point (° C.) |
| 1 | 68.4 | — | 24.5 | 5.5 | 1.6 | — | — | 494 |
| 2 | 69.9 | — | 8.7 | 19.7 | 1.6 | — | — | 489 |
| 3 | 76.0 | — | 21.8 | 0.8 | 1.4 | — | — | 426 |
| 4 | 76.5 | — | 17.2 | 4.9 | 1.4 | — | — | 433 |
| 5 | 77.0 | — | 12.5 | 9.1 | 1.4 | — | — | 433 |
| 6 | 78.1 | — | 12.4 | 5.4 | 4.1 | — | — | * |
| 7 | 82.4 | — | 15.0 | 0.7 | 1.9 | — | — | 373 |
| 8 | 82.5 | — | 15.9 | 0.4 | 1.2 | — | — | 377 |
| 9 | 82.9 | — | 13.5 | 2.7 | 0.9 | — | — | 374 |
| 10 | 83.1 | — | 11.2 | 4.5 | 1.3 | — | — | 378 |
| 11 | 83.2 | — | 11.5 | 4.7 | 0.6 | — | — | 383 |
| 12 | 84.0 | — | 2.6 | 12.0 | 1.3 | — | — | 407 |
| 13 | 88.0 | — | 10.2 | 0.7 | 1.1 | — | — | 336 |
| 14 | — | 58.9 | 15.5 | 3.5 | 0.8 | 17.9 | 3.4 | 503 |
| 15 | — | 68.5 | 10.1 | 2.9 | 0.7 | 15.0 | 2.9 | 464 |
| 16 | — | 73.0 | 9.5 | 1.0 | 0.5 | 13.0 | 3.0 | * |
| 17 | — | 73.2 | 8.2 | 1.9 | 0.6 | 13.5 | 2.6 | 447 |
| 18 | — | 75.1 | 8.6 | 0.4 | 0.6 | 12.8 | 2.5 | 433 |
| 19 | — | 77.6 | 9.1 | 1.7 | 0.5 | 8.7 | 2.4 | 438 |

* (not measured)

The glass frit can be 1 to 40 wt. % in an embodiment, 1.8 to 32 wt. % in another embodiment, 2.5 to 18 wt. % in another embodiment, 3 to 9 wt. % in still another embodiment, based on the weight of the conductive paste.

The glass frit can be 4 to 75 wt. % in an embodiment, 5 to 62 wt. % in another embodiment, 6 to 42 wt. % in another embodiment, 6 to 31 wt. % in another embodiment, and 7 to 17 wt. % in still another embodiment, based on the weight of solid in the conductive paste.

In still other embodiments, the glass frit can be 6 to 300 parts by weight, 6.5 to 200 parts by weight, 6.8 to 100 parts by weight, 7 to 100 parts by weight, 7.5 to 50 parts by weight, 8 to 20 parts by weight, 8.5 to 15 parts by weight, or 9.5 to 13 parts by weight, as the Ag powder is 100 parts by weight.

### Organic Medium

The organic medium is an organic resin or a mixture of an organic resin and a solvent. The organic medium can be, for example, a pine oil solution, an ethylene glycol monobutyl ether monoacetate solution of polymethacrylate, an ethylene glycol monobutyl ether monoacetate solution of ethyl cellulose, a terpineol solution of ethyl cellulose or a texanol solution of ethyl cellulose in an embodiment. The organic medium can be a terpineol solution of ethyl cellulose in another embodiment. The organic resin is 5 wt % to 50 wt % based on the weight of the organic medium in an embodiment.

The organic medium can be 10 to 60 wt. % in an embodiment, 15 to 57 wt. % in another embodiment, 22 to 53 wt. % in another embodiment, 35 to 50 wt. % in still another embodiment, based on the weight of the paste.

The organic medium can be 25 to 135 parts by weight in an embodiment, 55 to 129 parts by weight in another embodiment, and 80 to 121 parts by weight in still another embodiment, as the Ag powder is 100 parts by weight.

### Additives

Any of thickener, a stabilizer, or other typical additives can be included in the conductive paste. One or more additives can be determined dependent upon the characteristics of the conductive paste that are ultimately required.

The conductive paste can be produced by mixing each of the above-mentioned components with a mixer such as a roll mixing mill or a rotary mixer. A suitable amount of solvent can be added to adjust the viscosity to a value suitable for the deposition method to be used. The viscosity of the conductive paste is 50 to 350 Pa·s in an embodiment, 80 to 300 Pa·s in another embodiment, 95 to 220 Pa·s in another embodiment, as measured using a #14 spindle with a Brookfield HBT viscometer and with a utility cup at 10 rpm at 25° C.

A solar cell structured in the manner described above ideally exhibits good electrical and mechanical characteristics, including one or more of high light conversion efficiency, high fill factor, low series resistance, high shunt resistance, and good mechanical adhesion between the electrodes and the substrate.

Having thus described the invention in rather full detail, it will be understood that this detail need not be strictly adhered to but that further changes and modifications may suggest themselves to one skilled in the art, all falling within the scope of the invention as defined by the subjoined claims.

For example, a skilled person would recognize that the choice of raw materials could unintentionally include impurities that may be incorporated into the conductive paste composition during processing. These incidental impurities may be present in the range of hundreds to thousands of parts per million. Impurities commonly occurring in industrial materials used herein are known to one of ordinary skill.

The presence of the impurities would not substantially alter the chemical, rheological, and thermal properties of the conductive paste composition or its functionality in forming structures of the solar cell disclosed herein.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value. When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

In this specification, unless explicitly stated otherwise or indicated to the contrary by the context of usage, amounts, sizes, ranges, formulations, parameters, and other quantities and characteristics recited herein, particularly when modified by the term “about,” may but need not be exact, and may also be approximate and/or larger or smaller (as desired) than stated, reflecting tolerances, conversion factors, rounding off, measurement error, and the like, as well as the inclusion within a stated value of those values outside it that have, within the context of this invention, functional and/or operable equivalence to the stated value.

What is claimed is:

1. A method for manufacturing a passivated contact type solar cell, the method comprising the steps of:
(i) preparing a substrate comprising:
a first semiconductor layer,
a tunnel oxide layer on the first semiconductor layer,
a second semiconductor layer on the tunnel oxide layer,
a first insulating layer on the second semiconductor layer, and
a third semiconductor layer on the first semiconductor layer at the other side of the tunnel oxide layer,
wherein the second semiconductor layer is 0.2 to 400 nm thick and the first insulating layer comprises one or more openings;
(ii) applying a conductive paste in the openings of the first insulating layer, the conductive paste comprising:
(a) a conductive powder,
(b) a glass frit, and
(c) an organic vehicle; and
(iii) firing the applied conductive paste to form an electrode.

2. The method of claim 1, wherein the conductive powder comprises a powder of silver (Ag), palladium (Pd), an alloy comprising Ag and Pd, or a mixture thereof.

3. The method of claim 1, wherein the tunnel oxide layer is selected from the group consisting of titanium oxide, aluminum oxide, silicon nitride, silicon oxide, indium tin oxide, zinc oxide, silicon carbide, and a combination thereof.

4. The method of claim 1, wherein the tunnel oxide layer is 0.15 to 500 nm thick.

5. The method of claim 1, wherein the second semiconductor layer is a silicon layer.

6. The method of claim 1, wherein the first insulating layer is selected from the group consisting of Si₃N₄, TiO₂, and a combination thereof.

7. The method of claim 1, wherein the glass frit comprises 30 to 90 wt. % of at least one of PbO or Bi₂O₃, 1 to 50 wt. % of B₂O₃, 0.1 to 30 wt. % of SiO₂, and 0.1 to 20 wt. % of Al₂O₃.

8. The method of claim 7, wherein the glass frit further comprises ZnO or BaO.

9. The method of claim 1, wherein the conductive powder is 100 parts by weight and the glass frit is 0.1 to 50 parts by weight.

10. The method of claim 1, wherein the firing is carried out with a peak set point temperature of 400 to 950° C.

11. The method of claim 1, the substrate further comprises a second insulating layer on the third semiconductor layer.

12. A passivated contact type solar cell comprising:
(i) a substrate comprising a first semiconductor layer, a tunnel oxide layer on the first semiconductor layer, a second semiconductor layer on the tunnel oxide layer, a first insulating layer on the second semiconductor layer, a third semiconductor layer on the first semiconductor layer at the other side of the tunnel oxide layer, wherein the first insulating layer comprises one or more openings, wherein the second semiconductor layer is less than 20 nm thick; and
(ii) an electrode on the substrate wherein the electrode fills the openings the first insulating layer and contacts the second semiconductor layer, the electrode comprising (a) a metal and (b) a glass.

13. The passivated contact type solar cell of claim 12, wherein the metal comprises at least one of silver (Ag) or palladium (Pd).

14. The passivated contact type solar cell of claim 12, wherein the tunnel oxide layer is selected from the group consisting of titanium oxide, aluminum oxide, silicon nitride, silicon oxide, indium tin oxide, zinc oxide, silicon carbide, and a combination thereof.

15. The passivated contact type solar cell of claim 12, wherein the tunnel oxide layer is 0.15 to 500 nm thick.

16. The passivated contact type solar cell of claim 12, wherein the second semiconductor layer is a silicon layer.

17. The passivated contact type solar cell of claim 12, wherein the first insulating layer is selected from the group consisting of Si₃N₄, TiO₂, and a combination thereof.

18. The passivated contact type solar cell of claim 12, wherein the glass frit comprises 30 to 90 wt. % of at least one of PbO or Bi₂O₃, 1 to 50 wt. % of B₂O₃, 0.1 to 30 wt. % of SiO₂, and 0.1 to 20 wt. % of Al₂O₃.

19. The passivated contact type solar cell of claim 18, wherein the glass further comprises ZnO or BaO.

20. The passivated contact type solar cell of claim 12, wherein the conductive powder is 100 parts by weight and the glass frit is 0.1 to 50 parts by weight.

21. The passivated contact type solar cell of claim 12, wherein the substrate further comprises a second insulating layer on the third semiconductor layer.
